(19) United States
(12) Patent Application Publication
(10) Pub. No.: US 2026/0122993 A1
(43) Pub. Date: Apr. 30, 2026

(54) SEMICONDUCTOR DEVICE

(71) Applicant: SAMSUNG ELECTRONICS CO., LTD., Suwon-si (KR)

(72) Inventors: TAEHUN KIM, Suwon-si (KR); GYEONG-SEON PARK, Suwon-si (KR); JAEHYUK LIM, Suwon-si (KR); MINGU KO, Suwon-si (KR); YOUNG HWAN PARK, Suwon-si (KR); Jeonghwan PARK, Suwon-si (KR); Sewoong OH, Suwon-si (KR)

(73) Assignee: SAMSUNG ELECTRONICS CO., LTD., Suwon-si (KR)

(21) Appl. No.: 19/176,493

(22) Filed: Apr. 11, 2025

(30) Foreign Application Priority Data
Oct. 21, 2024 (KR) 10-2024-0143830

(51) Int. Cl. H01L 23/00; H10D 62/10

(52) U.S. Cl. CPC H10D 62/124; H10W 72/01323; H10W 72/07341; H10W 72/321; H10W 72/322; H10W 72/323; H10W 72/352; H10W 72/353; H10W 72/355; H10W 72/921; H10W 90/734; H10W 95/00

(57) ABSTRACT

Provided is a semiconductor device including a substrate, a semiconductor chip on the substrate, and a bonding layer between the substrate and the semiconductor chip, wherein the bonding layer includes a transition metal, a low-melting-point metal having a melting point lower than a melting point of the transition metal, a noble metal, and an alloy thereof, and a percentage of the noble metal in the bonding layer is greater in a central portion of the bonding layer than at peripheral portions of the bonding layer in a first direction of the bonding layer.

### CROSS-REFERENCE TO RELATED APPLICATION

This application claims priority to Korean Patent Application No. 10-2024-0143830 filed in the Korean Intellectual Property Office on Oct. 21, 2024, the disclosure of which is incorporated herein in its entirety by reference.

### BACKGROUND

Embodiments of the present disclosure relate to a semiconductor device.

Semiconductor devices are widely used in daily life. In particular, the importance of power semiconductor devices used in various fields such as transportation fields such as electric vehicles, railroads, and electric trams, renewable energy systems such as solar power generation and wind power generation, and mobile devices is gradually increasing. Power semiconductor devices are semiconductor devices used to handle relatively high voltage or high current, and perform functions such as power conversion and control in large power systems or high-output electronic devices. Power semiconductor devices have the ability and durability to handle relatively high power, so they may handle relatively large amounts of current and withstand high voltage. For example, power semiconductor devices may handle voltages from hundreds of volts to thousands of volts and currents from tens of amperes to thousands of amperes. Power semiconductor devices can improve the efficiency of electrical energy by minimizing power loss. Additionally, power semiconductor devices can be stably driven even in environments such as relatively high temperatures.

These power semiconductor devices can be classified according to materials, and examples include silicon carbide (SiC) power semiconductor devices and gallium nitride (GaN) power semiconductor devices. Power semiconductor devices are manufactured using SiC or GaN instead of silicon (Si) wafer, and thereby the disadvantage of silicon, which has unstable characteristics at relatively high temperatures, ma be compensated. The SiC power semiconductor devices are resistant to relatively high temperatures and have low power loss, and may be suitable for electric vehicles, renewable energy systems, etc. The GaN power semiconductor devices require relatively high costs, but are more efficient in terms of speed and may be suitable for high-speed charging of mobile devices.

### SUMMARY

One or more embodiments provide a semiconductor device in which a bonding layer for bonding a semiconductor chip and a substrate includes a high-melting-point solder material to enable high-temperature operation of the semiconductor chip while containing less noble metal to reduce cost, and in which the bonding layer includes a transition metal while preventing oxidation of the transition metal in the air and during the bonding process, suppressing void formation due to oxidation of the transition metal, reducing volume shrinkage, and improving bonding strength.

According to an aspect of one or more embodiments, there is provided a semiconductor device including a substrate, a semiconductor chip on the substrate, and a bonding layer between the substrate and the semiconductor chip, wherein the bonding layer includes a transition metal, a low-melting-point metal having a melting point lower than a melting point of the transition metal, a noble metal, and an alloy thereof, and a percentage of the noble metal in the bonding layer is greater in a central portion of the bonding layer than at peripheral portions of the bonding layer in a first direction of the bonding layer.

According to another aspect of one or more embodiments, there is provided a semiconductor device including a substrate, a semiconductor chip on the substrate, and a bonding layer between the substrate and the semiconductor chip, wherein the bonding layer includes, in a first direction of the bonding layer, a first layer on the semiconductor chip, a second layer on the substrate, an interface layer between the first layer and the second layer, a first diffusion barrier layer between the semiconductor chip and the first layer, and a second diffusion barrier layer between the substrate and the second layer, wherein the first layer and the second layer include nickel (Ni), tin (Sn), and an alloy thereof, wherein the interface layer includes nickel (Ni), tin (Sn), gold (Au), and an alloy thereof, and wherein the first diffusion barrier layer and the second diffusion barrier layer include titanium (Ti), titanium nitride (TiN), titanium tungsten (Ti—W), platinum (Pt), chromium (Cr), or a combination thereof.

According to still another aspect of one or more embodiments, there is provided a semiconductor device including a substrate, a semiconductor chip on the substrate, and a bonding layer between the substrate and the semiconductor chip, wherein the semiconductor chip includes a drain electrode, a first conductivity type semiconductor layer on the drain electrode, a second conductivity type doped well region in the first conductivity type semiconductor layer, a gate electrode on the first conductivity type semiconductor layer, a gate insulation layer between the first conductivity type semiconductor layer and the gate electrode, and a source electrode on the second conductivity type doped well region, wherein the bonding layer includes a transition metal, a low-melting-point metal having a melting point lower than that of the transition metal, and an alloy thereof, and wherein the drain electrode of the semiconductor chip includes the transition metal.

### BRIEF DESCRIPTION OF DRAWINGS

Embodiments will be more clearly understood from the following detailed description taken in conjunction with the accompanying drawings in which:

FIG. 1 is a cross-sectional view showing a semiconductor device according to one or more embodiments;

FIG. 2 is an enlarged cross-sectional view of the P region of FIG. 1;

FIG. 3 is a cross-sectional view showing a method for manufacturing a semiconductor device as illustrated in FIG. 2 according to one or more embodiments;

FIG. 4 is a cross-sectional view showing a semiconductor chip portion of a semiconductor device according to one or more embodiments;

FIG. 5 is a cross-sectional view showing a semiconductor device as illustrated in the P region of FIG. 1 according to one or more embodiments; and

FIG. 6 is a cross-sectional view showing a semiconductor device as illustrated in the P region of FIG. 1 according to one or more embodiments.

### DETAILED DESCRIPTION

Hereinafter, various embodiments of the present disclosure will be described in detail with reference to the attached drawings so that a person having ordinary skill in the art to which the present disclosure pertains can easily implement the present disclosure. The present disclosure may be embodied in many different forms and is not limited to the embodiments set forth herein.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

Additionally, throughout the specification, two directions parallel to and perpendicular to the upper surface of the substrate are defined as a first direction D1 and a second direction D2, respectively, and the direction perpendicular to the upper surface of the substrate is described as a third direction D3. For example, the first direction D1 and the second direction D2 may be the length direction and the width direction, respectively, and the third direction D3 may be the thickness direction.

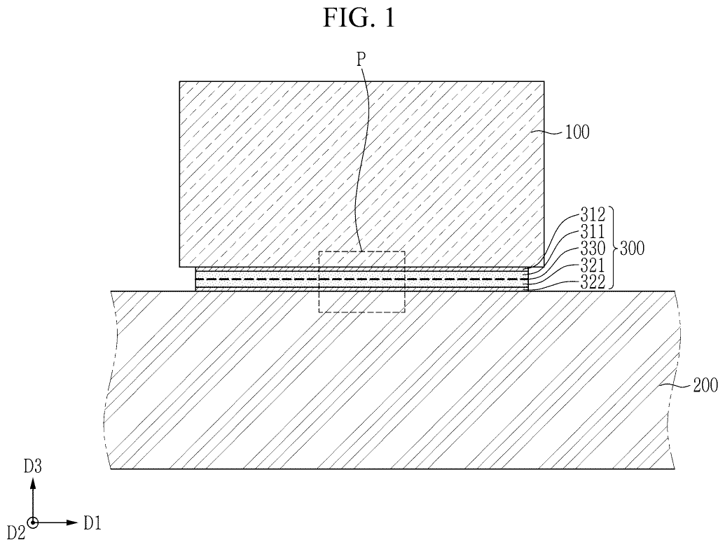

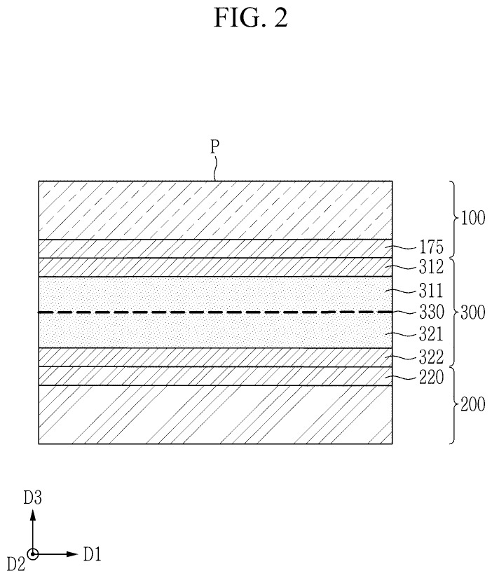

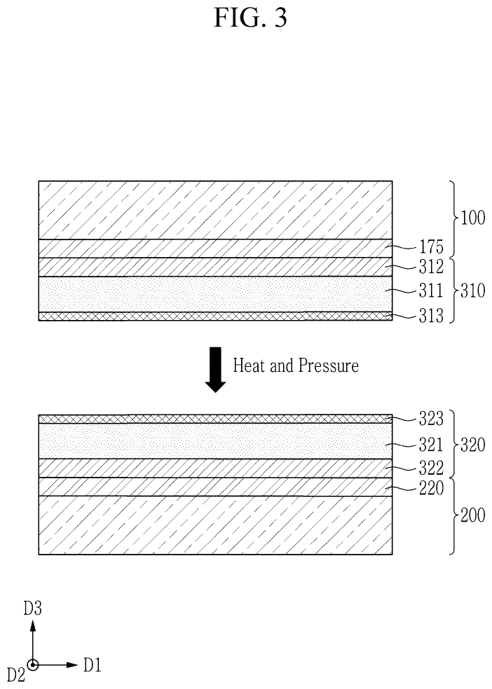

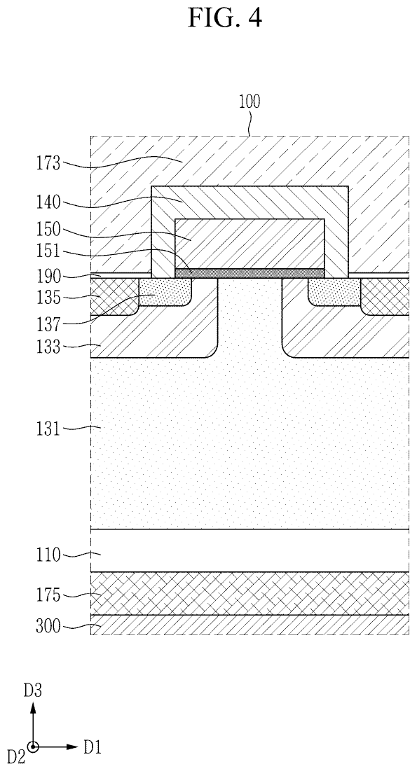

FIG. 1 is a cross-sectional view showing a semiconductor device according to one or more embodiments. FIG. 2 is an enlarged cross-sectional view of the P region of FIG. 1. FIG. 3 is a cross-sectional view showing a method for manufacturing a semiconductor device according to one or more embodiments, and is a drawing corresponding to FIG. 2. FIG. 4 is a cross-sectional view showing a semiconductor chip portion of a semiconductor device according to one or more embodiments.

For clear understanding and simple illustration, the detailed structures of the semiconductor chip 100 and the substrate 200 are omitted in FIG. 1, and the detailed structure of the bonding layer 300 is mainly illustrated.

Referring to FIGS. 1 to 4, the semiconductor device includes a substrate 200, a semiconductor chip 100 on the substrate 200, and a bonding layer 300 between the substrate 200 and the semiconductor chip 100.

First, referring to FIG. 3, a method for forming a bonding layer 300 will be described.

A mixed paste including a transition metal and a low-melting-point metal is prepared by mixing a transition metal and a low-melting-point metal having a lower melting point than the transition metal.

For example, when the semiconductor chip 100 is a silicon carbide (SIC) power semiconductor device described below, the semiconductor chip 100 may operate at 400° C. However, when the bonding layer 300 includes a related low-melting-point solder material, a peeling phenomenon occurs between the semiconductor chip 100 and the substrate 200 when the semiconductor chip 100 is driven at a relatively high temperature, so that the semiconductor chip cannot be driven at a relatively high temperature and the characteristics of the SiC power semiconductor device cannot be utilized.

Accordingly, the mixed paste for forming the bonding layer 300 is a high-melting-point solder including a transition metal and a low-melting-point metal, which enables the semiconductor chip 100 to be operated at relatively high temperatures.

The transition metal may include, for example, nickel (Ni), nickel vanadium (Ni—V), vanadium (V), titanium (Ti), tantalum (Ta), tungsten (W), copper (Cu), cobalt (Co), zinc (Zn), niobium (Nb), molybdenum (Mo), or a combination thereof. For example, the transition metal may be nickel (Ni) or nickel vanadium (Ni—V).

The low-melting-point metal may be a solder material that melts at lower temperatures than the transition metal. For example, the low-melting-point metal may include tin (Sn), lead (Pb), or a combination thereof, or may include tin (Sn). A tin (Sn) series solder material (lead-free solder) may include pure Sn, Sn—Ag, Sn—Ag—Cu, or Sn—Cu. The lead (Pb) series solder materials (flexible solders) may include Sn—Pb, etc.

The mixed paste may include a low-melting-point metal as a major component. For example, the content (percentage) of the low-melting-point metal in the mixed paste may be greater than or equal to about 90 at %. However, the composition and composition ratio of the mixed paste may vary.

The atomic ratio of transition metal to low-melting-point metal in the mixed paste may be greater than or equal to about 1:2.5. For example, the atomic ratio of transition metal to low-melting-point metal in the mixed paste may be about 1:3 to about 1:10. For example, when the content (percentage) of the low-melting-point metal is about 2.5 times or about 3 times more than that of the transition metal, the formation of an intermetallic compound through their reaction may be facilitated. However, depending on the type of transition metal and low-melting-point metal and the type of intermetallic compound to be formed, the composition and composition ratio of the transition metal and low-melting-point metal may vary.

The mixed paste may be prepared by mixing a first paste including a transition metal and a second paste including a low-melting-point metal. As another example, the mixed paste may be prepared by mixing a transition metal into a paste including a low-melting-point metal. Transition metals and low-melting-point metals may be uniformly distributed within the mixed paste. The mixed paste may further include a binder and a solvent in addition to the transition metal and the low-melting-point metal.

Next, the mixed paste may be applied to the lower surface of a semiconductor chip 100 to form a first solder layer 310, and a mixed paste may be applied to the upper surface of a substrate 200 to form a second solder layer 320.

For example, the mixed paste may be applied using a method such as screen printing. The thickness of the first solder layer 310 and the second solder layer 320 may each be greater than or equal to about 0.5 μm, for example, greater than or equal to about 2 μm, greater than or equal to about 3 μm, greater than or equal to about 4 μm, or greater than or equal to about 5 μm, and may be less than or equal to about 6 μm, for example less than or equal to about 5 μm, less than or equal to about 4 μm, or less than or equal to about 3 μm, and may be about 2 μm to about 6 μm, about 1 μm to about 3 μm, or about 2 μm to about 3 μm.

For example, the semiconductor chip 100 may be a power semiconductor device (power device). For example, the semiconductor chip 100 may be a power semiconductor device based on silicon (Si), SiC, or gallium nitride (GaN), or may be a SiC power semiconductor device. The semiconductor chip 100 may be a power device composed of elements such as an insulated gate bipolar transistor (IGBT), a metal-oxide-semiconductor field effect transistor (MOSFET), or a diode. Additionally, the semiconductor chip 100 may be a wide band gap (WBG) power semiconductor device based on, for example, SiC, GaN, or diamond.

The semiconductor chip 100 may include a metal layer on at least one surface, and a first solder layer 310 may be formed on the metal layer on the semiconductor chip 100. For example, the metal layer may be a drain electrode 175 described later.

For example, the substrate 200 may be one of various substrates used in a packaging process. For example, the substrate 200 may be a direct bonded copper (DBC) substrate, a direct bonded aluminum (DBA) substrate, a printed circuit board (PCB), or a lead frame.

For example, a DBC substrate may include a ceramic substrate and a first copper (Cu) layer and a second Cu layer on both surfaces of the ceramic substrate. The ceramic substrate may include aluminum oxide (Al₂O₃) or aluminum nitride (AlN), etc. At least one of the first Cu layer and the second Cu layer may have a patterned structure. When the first Cu layer and the second Cu layer are changed to aluminum (Al) layers, the substrate 200 may be a DBA substrate. For example, a DBA substrate is a substrate with an Al layer attached to both surfaces of a ceramic substrate. The PCB may include an organic (plastic) substrate, and the leadframe may be composed of metal. However, the material and composition of the substrate 200 are not limited thereto and may be modified in various ways.

The substrate 200 may include a metal wiring layer 220 such as a Cu layer on at least one surface, and a second solder layer 320 may be formed on the metal wiring layer 220.

Next, the lower surface of the semiconductor chip 100 on which the first solder layer 310 is formed and the upper surface of the substrate 200 on which the second solder layer 320 is formed may be bonded so that they face each other. For example, the bonding of the semiconductor chip 100 and the substrate 200 may be a die-attach process.

However, when forming a bonding layer 300 by bonding the first solder layer 310 on the lower surface of the semiconductor chip 100 and the second solder layer 320 on the upper surface of the substrate 200, when the first solder layer 310 and the second solder layer 320 include a transition metal and a low-melting-point metal, oxidation may occur in the air state, and voids may be formed due to oxidation during bonding.

Accordingly, the first solder layer 310 may further include a first noble metal layer 313 on the surface, and the second solder layer 320 may further include a second noble metal layer 323 on the surface. The first noble metal layer 313 and the second noble metal layer 323 may prevent the transition metal of the first solder layer 310 and the second solder layer 320 from being oxidized in the air state or during bonding.

For example, the first noble metal layer 313 and the second noble metal layer 323 may include a noble metal. For example, the noble metal included in the first noble metal layer 313 and the second noble metal layer 323 may include silver (Ag), gold (Au), platinum (Pt), ruthenium (Ru), rhodium (Rh), palladium (Pd), iridium (Ir), osmium (Os), or a combination thereof.

For example, the thicknesses of the first noble metal layer 313 and the second noble metal layer 323 may each be less than or equal to about 10 nm. Such thickness of the first noble metal layer 313 and the second noble metal layer 323 may be a factor in reducing a thickness of the first solder layer 310 and the second solder layer 320 that are bonded.

The noble metal included in the first noble metal layer 313 and the second noble metal layer 323 may diffuse into the first solder layer 310 and the second solder layer 320 during bonding to form an interface layer 330 in the bonding layer 300. The interface layer 330 of the bonding layer 300 may increase bonding strength and reduce volume reduction during bonding.

In addition, when the first solder layer 310 and the second solder layer 320 include a transition metal and a low-melting-point metal, it may be difficult for the transition metal to be dissolved into the low-melting-point metal, and thus many voids may occur in the bonding layer 300. When the drain electrode 175 of the semiconductor chip 100 includes a transition metal, the contact characteristics of the drain electrode 175 may deteriorate as the transition metal of the drain electrode 175 is mixed with the bonding layer 300 during bonding.

Accordingly, a first diffusion barrier layer 312 may be additionally formed between the lower surface of the semiconductor chip 100 and the first solder layer 310, and a second diffusion barrier layer 322 may be additionally formed between the upper surface of the substrate 200 and the second solder layer 320.

The first diffusion barrier layer 312 may be formed on the lower surface of the semiconductor chip 100, for example, on the lower surface of the drain electrode 175, before forming the first solder layer 310, and then the first solder layer 310 may be formed on the lower surface of the first diffusion barrier layer 312.

The second diffusion barrier layer 322 may be formed on the upper surface of the substrate 200, for example, on the upper surface of the metal wiring layer 220, before forming the second solder layer 320, and then the second solder layer 320 may be formed on the upper surface of the second diffusion barrier layer 322.

The first diffusion barrier layer 312 and the second diffusion barrier layer 322 may prevent the contact characteristics of the drain electrode 175 from being deteriorated when the transition metal of the drain electrode 175 is mixed with the bonding layer 300 during bonding.

For example, bonding of a semiconductor chip 100 and a substrate 200 may be accomplished using a high pressure bonding method. For example, the semiconductor chip 100 and the substrate 200 may be bonded not only by applying temperature but also by applying relatively high pressure when bonding the semiconductor chip 100 and the substrate 200.

When applying a high pressure bonding method, in addition to bonding of the semiconductor chip 100 and the substrate 200, wafer bonding may also be performed on the substrate 200, and the occurrence of voids in the bonding layer 300 can be additionally prevented.

At this time, the temperature may be greater than or equal to about 200° C., for example, greater than or equal to about 250° C., greater than or equal to about 300° C., greater than or equal to about 350° C., greater than or equal to about 400° C., greater than or equal to about 450° C., greater than or equal to about 500° C., or greater than or equal to about 550° C., and may be, for example, for example less than or equal to about 600° C., less than or equal to about 550° C., less than or equal to about 500° C., less than or equal to about 450° C., less than or equal to about 400° C., less than or equal to about 350° C., less than or equal to about 300° C., or less than or equal to about 250° C., for example, about 200° C. to about 600° C.

The pressure may be greater than or equal to about 1 m Torr, for example greater than or equal to about 5 m Torr, greater than or equal to about 10 m Torr, greater than or equal to about 50 m Torr, greater than or equal to about 100 m Torr, greater than or equal to about 200 m Torr, greater than or equal to about 300 m Torr, greater than or equal to about 400 m Torr, greater than or equal to about 500 m Torr, greater than or equal to about 600 m Torr, greater than or equal to about 700 m Torr, greater than or equal to about 800 m Torr, or greater than or equal to about 900 m Torr, for example less than or equal to 1000 m Torr, less than or equal to 900 m Torr, less than or equal to 800 m Torr, less than or equal to 700 m Torr, less than or equal to 600 m Torr, less than or equal to 500 m Torr, less than or equal to 400 m Torr, less than or equal to 300 m Torr, less than or equal to 200 m Torr, or less than or equal to 100 m Torr, for example about 1 m Torr to about 1000 m Torr.

As described above, when the first solder layer 310 further includes a first noble metal layer 313 on the surface, and the second solder layer 320 further includes a second noble metal layer 323 on the surface, the noble metals included in the first noble metal layer 313 and the second noble metal layer 323 may diffuse into the first solder layer 310 and the second solder layer 320 during bonding.

Accordingly, the bonding layer 300 may include a transition metal, a low-melting-point metal, a noble metal, and an alloy thereof.

For example, when the transition metal included in the first solder layer 310 and the second solder layer 320 is nickel (Ni), the low-melting-point metal is tin (Sn), and the noble metal included in the first noble metal layer 313 and the second noble metal layer 323 is gold (Au), the bonding layer 300 may include nickel (Ni), tin (Sn), and gold (Au), and an alloy thereof such as nickel-tin (Ni—Sn) and gold-tin (Au—Sn).

For example, the content (percentage) of the transition metal, the low-melting-point metal, and the alloy thereof in the bonding layer 300 may be greater than or equal to about 95 at %, greater than or equal to about 96 at %, greater than or equal to about 97 at %, or greater than or equal to about 98 at %, and less than or equal to about 99 at %, for example, less than or equal to about 98 at %, less than or equal to about 97 at %, or less than or equal to about 96 at %, and about 95 at % to about 99 at %. Additionally, the content (percentage) of the noble metal, and the alloy of the noble metal and the low-melting-point metal in the bonding layer 300 may be greater than or equal to about 1 at %, for example, greater than or equal to about 2 at %, greater than or equal to about 3 at %, or greater than or equal to about 4 at %, and may be less than or equal to about 5 at %, for example, less than or equal to about 4 at %, less than or equal to about 3 at %, or less than or equal to about 2 at %, and may be about 1 at % to about 5 at %.

The first solder layer 310 and the second solder layer 320 are bonded to form a bonding layer 300, and when bonded, the first noble metal layer 313 and the second noble metal layer 323 contact each other and the noble metal diffuses into the bonding layer 300, so that the noble metal may be mainly located at approximately the middle in the thickness direction (third direction D3) of the bonding layer 300. For example, the content (percentage) of the noble metal in the bonding layer 300 may be greater in an interior (a central portion) of the bonding layer 300 than at two surfaces (peripheral portions) of the bonding layer 300 in the third direction D3. Here, the interior of the bonding layer 300 may be a center (½ point) point in the third direction D3 of the bonding layer 300, and two surfaces of the bonding layer 300 may be the interface between the bonding layer 300 and the semiconductor chip 100 and the bonding layer 300 and the substrate 200. For example, the content (percentage) of the noble metal within the bonding layer 300 may decrease from the center of the bonding layer 300 to the upper surface and lower surface of the bonding layer 300.

The bonding layer 300 may have a first layer 311 closer to the semiconductor chip 100 than the substrate 200 in the third direction D3, a second layer 321 closer to the substrate 200 than the semiconductor chip 100, and an interface layer 330 between the first layer 311 and the second layer 321. For example, the second layer 321, the interface layer 330, and the first layer 311 may be sequentially stacked in the third direction D3. The second layer 321, the interface layer 330, and the first layer 311 may be overlapped in the third direction D3.

For example, the content (percentage) of the noble metal in the bonding layer 300 may be measured by analyzing a cross-sectional image (e.g., FIG. 2) obtained by cutting the semiconductor device in the first direction D1 and the third direction D3 perpendicular to the second direction D2 from the center (½ point) of the second direction D2 using an electron beam microanalyzer (EPMA) and observing the cross-sectional image using a scanning electron microscope (SEM) or a scanning transmission electron microscope (STEM). When performing component analysis, etc. using an electron beam microanalyzer (EPMA), an energy dispersive spectrometer (EDS) or wavelength dispersive spectrometer (WDS) can be used as an X-ray spectrometer.

For example, the interface layer 330 may be, in cross-section, a region in which the content (percentage) of the noble metal in the bonding layer 300 from the center (½ point) upwards and downwards in the third direction D3 of the bonding layer 300 is, for example, greater than or equal to about 50 at %, greater than or equal to about 60 at %, greater than or equal to about 70 at %, greater than or equal to about 80 at %, greater than or equal to about 90 at %, or greater than or equal to about 100 at %. The first layer 311 may be a region between the interface layer 330 and the semiconductor chip 100, and the second layer 321 may be a region between the interface layer 330 and the substrate 200.

However, as described above, since the content (percentage) of the noble metal in the bonding layer 300 is a relatively small amount, such as about 1 at % to about 5 at %, the boundary between the interface layer 330 whose main components are a transition metal and a low-melting-point metal, and the first layer 311 and the second layer 321 may not be clearly distinguished with the naked eye.

Accordingly, the content (percentage) of the noble metal in the interface layer 330 may be, for example, greater than or equal to about 50 at %, greater than or equal to about 60 at %, greater than or equal to about 70 at %, greater than or equal to about 80 at %, greater than or equal to about 90 at %, or greater than or equal to about 100 at % based on the content (percentage) of the noble metal in the bonding layer 300. Additionally, the content (percentage) of the noble metal in each of the first layer 311 and the second layer 321 may be, for example, less than about 50 at %, less than about 40 at %, less than about 30 at %, less than about 20 at %, less than about 10 at %, or 0 at % based on the content (percentage) of the noble metal in the bonding layer 300. In other words, the content (percentage) of the noble metal within the bonding layer 300 may be higher in the interface layer 330 than in the first layer 311 and the second layer 321. For example, the first layer 311 and the second layer 321 may include a transition metal, a low-melting-point metal, and an alloy thereof, and the interface layer 330 may include a transition metal, a low-melting-point metal, a noble metal, and an alloy thereof.

The content (percentage) of the noble metal of the interface layer 330 may be greater in the interior of the interface layer 330 than at both surfaces of the interface layer 330 in the thickness direction (third direction D3) of the interface layer 330. Here, the interior of the interface layer 330 may be the center (½ point) point in the third direction D3 of the interface layer 330, and both surfaces of the interface layer 330 may be a boundary between the interface layer 330 and the first layer 311 and the second layer 321. For example, the content (percentage) of the noble metal in the interface layer 330 may gradually decrease from the interior of the interface layer 330 to both surfaces of the interface layer 330 in the thickness direction (third direction D3) of the interface layer 330.

For example, the thickness of the interface layer 330 may be less than or equal to about 50%, for example less than or equal to about 40%, less than or equal to about 30%, less than or equal to about 20%, less than or equal to about 10%, or less than or equal to about 5%, and greater than or equal to about 1%, greater than or equal to about 5%, greater than or equal to about 10%, greater than or equal to about 20%, greater than or equal to about 30%, or greater than or equal to about 40%, and may be about 1% to about 50%, or about 1% to about 5% relative to the thickness of the bonding layer 300.

For example, the thickness of the bonding layer 300 may be greater than or equal to about 1 μm, for example, greater than or equal to about 2 μm, greater than or equal to about 3 μm, greater than or equal to about 4 μm, greater than or equal to about 5 μm, greater than or equal to about 6 μm, greater than or equal to about 7 μm, greater than or equal to about 8 μm, or greater than or equal to about 9 μm, and may be less than or equal to about 10 μm, for example, less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, or less than or equal to about 2 μm, and may be about 1 μm to about 10 μm, for example, about 2 μm to about 6 μm, or about 4 μm to about 6 μm.

The thickness of the interface layer 330 may be less than or equal to about 20 nm, for example 15 nm, less than or equal to about 10 nm, or less than or equal to about 5 nm, and greater than or equal to about 1 nm, greater than or equal to about 5 nm, greater than or equal to about 10 nm, or greater than or equal to about 15 nm, or may be about 1 nm to about 20 nm.

The thickness of the first layer 311 may be greater than or equal to about 2 μm, for example greater than or equal to about 3 μm, greater than or equal to about 4 μm, or greater than or equal to about 5 μm, and may be less than or equal to about 6 μm, for example 5 μm, less than or equal to about 4 μm, or less than or equal to about 3 μm, and may be about 2 μm to about 6 μm, or about 2 μm to about 3 μm.

The thickness of the second layer 321 may be greater than or equal to about 2 μm, for example greater than or equal to about 3 μm, greater than or equal to about 4 μm, or greater than or equal to about 5 μm, and may be less than or equal to 6 μm, for example 5 μm, less than or equal to about 4 μm, or less than or equal to about 3 μm, and may be about 2 μm to about 6 μm, or about 2 μm to about 3 μm.

The bonding layer 300 may have voids. For example, the bonding layer 300 may have voids in the interface layer 330. For example, in cross-section, the voids may be located primarily at the center (½ point) in the third direction D3 of the bonding layer 300.

As described above, when the bonding layer 300 includes a transition metal and a low-melting-point metal, it may be difficult for the transition metal to dissolve into the low-melting-point metal, and thus many voids may occur within the bonding layer 300. However, when a high pressure bonding method is used during bonding, generation of voids may be prevented. Accordingly, the bonding layer 300 may have only a relatively small amount of voids in the interface layer 330.

The bonding layer 300 may have voids of less than or equal to about 5 volume %, for example less than or equal to about 4 volume %, less than or equal to about 3 volume %, or less than or equal to about 2 volume %, and greater than or equal to about 1 volume %, for example greater than or equal to about 2 volume %, greater than or equal to about 3 volume %, or greater than or equal to about 4 volume %, and may have about 1 volume % to about 5 volume %.

The bonding layer 300 may further have a first diffusion barrier layer 312 and a second diffusion barrier layer 322.

As described above, when the bonding layer 300 includes a transition metal and a low-melting-point metal, and the drain electrode 175 of the semiconductor chip 100 includes a transition metal, the contact characteristics of the drain electrode 175 may deteriorate when the transition metal of the drain electrode 175 is mixed with the bonding layer 300 during bonding. However, the first diffusion barrier layer 312 and the second diffusion barrier layer 322 may prevent the contact characteristics of the drain electrode 175 from deteriorating when the transition metal of the drain electrode 175 is mixed with the bonding layer 300 during bonding.

The first diffusion barrier layer 312 may be located between the semiconductor chip 100 and the first layer 311, and the second diffusion barrier layer 322 may be located between the substrate 200 and the second layer 321. For example, the second diffusion barrier layer 322, the second layer 321, the interface layer 330, the first layer 311, and the first diffusion barrier layer 312 may be sequentially stacked in the third direction D3. The first diffusion barrier layer 312 and the second diffusion barrier layer 322 may be overlapped with the second layer 321, the interface layer 330, and the first layer 311 in the third direction D3.

For example, the first diffusion barrier layer 312 and the second diffusion barrier layer 322 may include titanium (Ti), titanium nitride (TiN), titanium tungsten (Ti-W), platinum (Pt), chromium (Cr), or a combination thereof, and may include, for example, titanium (Ti), titanium nitride (TiN), or titanium tungsten (Ti—W). The first diffusion barrier layer 312 and the second diffusion barrier layer 322 may be formed as a single layer or multiple layers.

For example, the thickness of the first diffusion barrier layer 312 may be greater than or equal to about 100 nm, for example, greater than or equal to about 1 μm, greater than or equal to about 2 μm, greater than or equal to about 3 μm, greater than or equal to about 4 μm, greater than or equal to about 5 μm, greater than or equal to about 6 μm, greater than or equal to about 7 μm, greater than or equal to about 8 μm, or greater than or equal to about 9 μm, and may be less than or equal to about 10 μm, for example less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm, and may be about 100 nm to about 10 μm, or about 100 nm to about 3 μm.

The thickness of the second diffusion barrier layer 322 may be greater than or equal to about 100 nm, for example, greater than or equal to about 1 μm, greater than or equal to about 2 μm, greater than or equal to about 3 μm, greater than or equal to about 4 μm, greater than or equal to about 5 μm, greater than or equal to about 6 μm, greater than or equal to about 7 μm, greater than or equal to about 8 μm, or greater than or equal to about 9 μm, and may be less than or equal to about 10 μm, for example less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm, and may be about 100 nm to about 10 μm, or about 100 nm to about 3 μm.

Hereinafter, with reference to FIG. 4, as an example, when the semiconductor chip 100 is a SiC power semiconductor device will be described.

A semiconductor chip 100 may include a chip substrate 110, a first conductivity type semiconductor layer 131 on a first surface of the chip substrate 110, a second conductivity type doped well region 133 within the first conductivity type semiconductor layer 131, a gate electrode 150 on the first conductivity type semiconductor layer 131 and the second conductivity type doped well region 133, a gate insulation layer 151 between the first conductivity type semiconductor layer 131 and the gate electrode 150, a first interlayer insulation layer 140 covering an upper surface and a side surface of the gate electrode 150, a source electrode 173 on the second conductivity type doped well region 133, and a drain electrode 175 on the second surface of the chip substrate 110.

The chip substrate 110 may be a semiconductor substrate including SiC. For example, the chip substrate 110 may be made of a 4H SiC substrate. In some examples, the chip substrate 110 may be made of a 3C SiC substrate, a 6H SiC substrate, etc. The chip substrate 110 may be doped with a first conductivity type impurity.

For example, the first conductivity type impurity may be an n-type impurity. For example, the chip substrate 110 may be doped with n type. The chip substrate 110 may be heavily doped with n-type. The resistivity of the chip substrate 110 may be greater than or equal to about 0.005 Ωcm and less than or equal to about 0.035 Ωcm. The thickness of the chip substrate 110 may be greater than or equal to about 100 μm and less than or equal to about 700 μm. The material, doping type, doping concentration, resistivity, thickness, etc. of the chip substrate 110 are not limited thereto and may be changed in various ways. The chip substrate 110 may include a first surface and a second surface facing each other. The first surface of the chip substrate 110 may be the upper surface of the chip substrate 110, and the second surface of the chip substrate 110 may be the lower surface of the chip substrate 110.

The first conductivity type semiconductor layer 131 may be located on the first surface, i.e., the upper surface, of the chip substrate 110. The lower surface of the first conductivity type semiconductor layer 131 may be in contact with the upper surface of the chip substrate 110. However, embodiments are not limited thereto, and another layer may be additionally located between the chip substrate 110 and the first conductivity type semiconductor layer 131. The first conductivity type semiconductor layer 131 may be an epitaxial layer formed from a chip substrate 110 using an epitaxial growth method. The first conductivity type semiconductor layer 131 may include SiC. For example, the first conductivity type semiconductor layer 131 may include 4H SiC. The first conductivity type semiconductor layer 131 may be doped as n type. The first conductivity type semiconductor layer 131 may be lightly doped as an n type. The doping concentration of the first conductivity type semiconductor layer 131 may be lower than the doping concentration of the chip substrate 110. The doping concentration of the first conductivity type semiconductor layer 131 may be greater than or equal to about 1*10¹⁵ cm⁻³ and less than or equal to about 1*10¹⁷ cm⁻³. The thickness of the first conductivity type semiconductor layer 131 may be greater than or equal to about 1 μm and less than or equal to about 13 μm. The material, doping type, doping concentration, etc. of the first conductivity type semiconductor layer 131 are not limited thereto and may be changed in various ways.

The second conductivity type doped well region 133 may be located within the first conductivity type semiconductor layer 131. The second conductivity type doped well region 133 may be located on top of the first conductivity type semiconductor layer 131. The second conductivity type doped well region 133 may be in contact with the lower surface of the second conductivity type doped layer 135 to be described later. The second conductivity type doped well region 133 may surround the lower surface and side surface of the first conductivity type doped layer 137 to be described later.

At least a portion of the upper surface of the second conductivity type doped well region 133 may be overlapped with at least a portion of the gate electrode 150 to be described later and at least a portion of the gate insulation layer 151 to be described later in the third direction D3.

The second conductivity type doped well region 133 may extend from the upper surface of the first conductivity type semiconductor layer 131 toward the lower surface of the first conductivity type semiconductor layer 131. For example, the second conductivity type doped well region 133 may extend in the third direction D3 from the upper surface of the first conductivity type semiconductor layer 131. The second conductivity type doped well region 133 may be formed in at least a portion of the first conductivity type semiconductor layer 131 through ion implantation.

The second conductivity type doped well region 133 may include SiC. For example, the second conductivity type doped well region 133 may include 4H SiC. The second conductivity type doped well region 133 may be doped with p type. The second conductivity type doped well region 133 may be lightly doped as a p type. The doping concentration of the second conductivity type doped well region 133 may be greater than or equal to about 1*10¹⁷ cm⁻³ and less than or equal to about 1*10¹⁹ cm⁻³. The material, doping type, doping concentration, etc. of the second conductivity type doped well region 133 are not limited thereto and may be changed in various ways.

The semiconductor chip 100 may further include a second conductivity type doped layer 135 and a first conductivity type doped layer 137 located on top of the first conductivity type semiconductor layer 131.

The second conductivity type doped layer 135 may be located within the second conductivity type doped well region 133. The second conductivity type doped layer 135 is located on top of the first conductivity type semiconductor layer 131 and may have an upper surface that is in direct contact with the lower surface of the silicide layer 190 connected to the source electrode 173 to be described later.

At least a portion of the upper surface of the second conductivity type doped layer 135 may be in contact with the lower surface of the silicide layer 190 to be described later, but is not limited thereto. For example, at least a portion of the upper surface of the second conductivity type doped layer 135 may be in contact with the lower surface of the source electrode 173. At this time, the second conductivity type doped layer 135 may have a width wider than a width of the source electrode 173.

The second conductivity type doped layer 135 may extend in the third direction D3 from the upper surface of the first conductivity type semiconductor layer 131. At this time, a thickness of the second conductivity type doped layer 135 along the third direction D3 may be less than a thickness of the second conductivity type doped well region 133 along the third direction D3. Additionally, the second conductivity type doped layer 135 may have a width less than a width of the second conductivity type doped well region 133. For example, the second conductivity type doped layer 135 may be buried within the second conductivity type doped well region 133. The second conductivity type doped layer 135 may be formed in at least a portion of the second conductivity type doped well region 133 through ion implantation.

The second conductivity type doped layer 135 may include SiC. For example, the second conductivity type doped layer 135 may include 4H SiC. The second conductivity type doped layer 135 may be doped with p type. The second conductivity type doped layer 135 may form an ohmic contact with the source electrode 173. For this purpose, the second conductivity type doped layer 135 may be doped at a high concentration as a p type. In one or more embodiments, the doping concentration of the second conductivity type doped layer 135 may be greater than the doping concentration of the second conductivity type doped well region 133. The doping concentration of the second conductivity type doped layer 135 may be greater than or equal to about 1*10¹⁸ cm⁻³ and less than or equal to about 5*10²⁰ cm⁻³. The material, doping type, doping concentration, etc. of the second conductivity type doped layer 135 are not limited thereto and may be changed in various ways.

The first conductivity type doped layer 137 may be located within the second conductivity type doped well region 133. The first conductivity type doped layer 137 may be located on top of the first conductivity type semiconductor layer 131 and may be provided adjacent to and surround both sides of the second conductivity type doped layer 135. The upper surface of the first conductivity type doped layer 137 may be overlapped at least a portion of the gate electrode 150 and at least a portion of the gate insulation layer 151 in the third direction D3, which will be described later. In addition, the upper surface of the first conductivity type doped layer 137 may be overlapped at least a portion of the source electrode 173 to be described later in the third direction D3, but is not limited thereto. The upper surface of the first conductivity type doped layer 137 may directly contact the gate insulation layer 151 to be described later.

The first conductivity type doped layer 137 may extend in the third direction D3 from the upper surface of the first conductivity type semiconductor layer 131. The first conductivity type doped layer 137 may be buried within the second conductivity type doped well region 133. At this time, a thickness of the first conductivity type doped layer 137 along the third direction D3 may be smaller than a thickness of the second conductivity type doped well region 133 along the third direction D3.

The first conductivity type doped layer 137 may be a doping region formed using an ion implantation process within the first conductivity type semiconductor layer 131. The first conductivity type doped layer 137 may include SiC. For example, the first conductivity type doped layer 137 may include 4H SiC. The first conductivity type doped layer 137 may be doped with n type. The first conductivity type doped layer 137 may be highly doped as an n type. The doping concentration of the first conductivity type doped layer 137 may be greater than or equal to about 1*10¹⁸ cm⁻³ and less than or equal to about 5*10²⁰ cm⁻³. The material, doping type, doping concentration, etc. of the first conductivity type doped layer 137 are not limited thereto and may be changed in various ways.

The gate electrode 150 may be located on the first conductivity type semiconductor layer 131. The gate electrode 150 may be spaced apart from the first conductivity type semiconductor layer 131. For example, the gate electrode 150 may be spaced apart from the first conductivity type semiconductor layer 131 in a vertical direction (e.g., in the thickness direction of the chip substrate 110, the third direction D3) by a gate insulation layer 151 that is between the gate electrode 150 and the first conductivity type semiconductor layer 131. In one or more embodiments, the semiconductor chip 100 may have a planar-shaped gate structure. For example, in the semiconductor chip 100, the gate electrode 150 has a flat plate shape with the upper and lower surfaces being flat, and the lower surface of the gate electrode 150 may be located at a level greater (higher) than a level of the uppermost surface of the first conductivity type semiconductor layer 131 in the third direction D3. However, embodiments are not limited thereto, and the semiconductor chip 100 according to one or more embodiments may have, for example, a trench-shaped gate structure. For example, in a semiconductor chip 100, a trench of a predetermined depth is formed in a first conductivity type semiconductor layer 131, and a gate electrode 150 may be located inside the trench spaced apart from the first conductivity type semiconductor layer 131 in a third direction D3. Additionally, the gate electrode 150 may be located spaced apart from the first conductivity type semiconductor layer 131 in the first direction D1 and/or the second direction D2.

The gate electrode 150 may be overlapped with the second conductivity type doped well region 133 and the first conductivity type doped layer 137 in the third direction D3. The gate electrode 150 may include a conductive material. For example, the gate electrode 150 may include polysilicon doped with impurities. As another example, the gate electrode 150 may include a metal, a metal alloy, a conductive metal nitride, a metal silicide, a doped semiconductor material, a conductive metal oxide, a conductive metal nitride, or a combination thereof. The gate electrode 150 may be formed of a single layer or multiple layers.

The gate insulation layer 151 may be located between the first conductivity type semiconductor layer 131 and the gate electrode 150. For example, the gate insulation layer 151 may be located under the gate electrode 150 and may be provided on and cover the lower surface of the gate electrode 150. The gate electrode 150 may be insulated from the first conductivity type semiconductor layer 131 by a gate insulation layer 151. A thickness of the gate insulation layer 151 may be almost constant.

The gate insulation layer 151 may be overlapped with the second conductivity type doped well region 133 and the first conductivity type doped layer 137 in the third direction D3. The lower surface of the gate insulation layer 151 may be in direct contact with the second conductivity type doped well region 133 and the first conductivity type doped layer 137, but is not limited thereto. The gate insulation layer 151 may include an insulating material. For example, the gate insulation layer 151 may include SiO₂. However, the present disclosure is not limited thereto, and the material of the gate insulation layer 151 can be changed in various ways. As another example, the gate insulation layer 151 may include silicon nitride (SIN), silicon oxynitride (SiON), SiC, silicon carbonitride (SiCN), or a combination thereof. The gate insulation layer 151 may be formed of a single layer or multiple layers.

The first interlayer insulation layer 140 may be located on the first conductivity type semiconductor layer 131. For example, the first interlayer insulation layer 140 may be located on the gate electrode 150. For example, the first interlayer insulation layer 140 may be provided on and cover the upper surface and side surface of the gate electrode 150. The first interlayer insulation layer 140 may be provided on and cover the side surface of the gate insulation layer 151. The first interlayer insulation layer 140 may also be located on an upper surface of the first conductivity type doped layer 137. The first interlayer insulation layer 140 may have a lower surface that is in contact with at least a portion of the upper surface of the first conductivity type doped layer 137. The gate electrode 150 may be insulated from the source electrode 173 by the first interlayer insulation layer 140.

The first interlayer insulation layer 140 may include an insulating material. For example, the first interlayer insulation layer 140 may include the same insulating material as the gate insulation layer 151. For example, the first interlayer insulation layer 140 may include SiO₂. However, embodiments are not limited thereto, and the first interlayer insulation layer 140 may include various types of insulating materials to insulate the gate electrode 150 from the source electrode 173. For example, the first interlayer insulation layer 140 may include SiOP, SiN, SiON, or a combination thereof. The first interlayer insulation layer 140 may be formed of a single layer or multiple layers. When the first interlayer insulation layer 140 is made of the same material as the gate insulation layer 151, a boundary between the first interlayer insulation layer 140 and the gate insulation layer 151 may not be clearly distinguished at the portion where the first interlayer insulation layer 140 and the gate insulation layer 151 are in contact with each other.

The source electrode 173 may be located on the second conductivity type doped well region 133. A second conductivity type doped layer 135 and a first conductivity type doped layer 137 may be located between the source electrode 173 and the second conductivity type doped well region 133. The source electrode 173 may be electrically connected to the second conductivity type doped well region 133 by the second conductivity type doped layer 135. The source electrode 173 may be located on both sides of the gate electrode 150. However, embodiments are not limited thereto, and the source electrode 173 may be located only on one side of the gate electrode 150. A first interlayer insulation layer 140 may be located between the source electrode 173 and the gate electrode 150. Through the source electrode 173, current or voltage may be provided to the semiconductor chip 100. The source electrode 173 may be separated from the gate electrode 150 by the first interlayer insulation layer 140. The source electrode 173 may be in contact with the side surface of the first interlayer insulation layer 140.

For example, a portion of a source electrode 173 may be located between adjacent gate electrodes 150 in the first direction D1 is overlapped with the second conductivity type doped layer 135 and the first conductivity type doped layer 137 in the third direction D3, but embodiments are not limited thereto. For example, a portion of a source electrode 173 located between adjacent gate electrodes 150 in the first direction D1 may not be overlapped with the first conductivity type doped layer 137 in the third direction D3. At this time, the upper surface of the first conductivity type doped layer 137 may be provided on and covered by a gate insulation layer 151.

The source electrode 173 may include a conductive material. For example, the source electrode 173 may include a metal, a metal alloy, a conductive metal nitride, a metal silicide, a doped semiconductor material, a conductive metal oxide, or a conductive metal nitride. For example, the source electrode 173 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC—N), titanium aluminum carbide (TiAlC), titanium carbide (TiC), tantalum carbide nitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MON), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto. The source electrode 173 may be formed of a single layer or multiple layers.

The semiconductor chip 100 may further include a silicide layer 190 between the source electrode 173 and the second conductivity type doped layer 135 and between the source electrode 173 and the first conductivity type doped layer 137.

The silicide layer 190 may be conformally located along the interface between the source electrode 173 and the second conductivity type doped layer 135 and between the source electrode 173 and the first conductivity type doped layer 137. The lower surface of the silicide layer 190 may directly contact the second conductivity type doped layer 135 and the first conductivity type doped layer 137. The upper surface of the silicide layer 190 may be in direct contact with the source electrode 173. The silicide layer 190 may include a metal silicide material. For example, the silicide layer 190 may include tungsten silicide (WSi), titanium silicide (TiSi), cobalt silicide (CoSi), nickel silicide (NiSi), or a combination thereof.

In the manufacturing process of the semiconductor chip 100, a silicidation process can be performed on the upper surface of the second conductivity type doped layer 135 and the first conductivity type doped layer 137 to form a silicide layer 190. However, embodiments are not limited thereto, and after forming the source electrode 173, an annealing process may be performed subsequently to reduce the contact resistance between the second conductivity type doped layer 135 and the source electrode 173 and between the first conductivity type doped layer 137 and the source electrode 173. Accordingly, a silicide layer 190 may be formed along the interface between the source electrode 173 and the second conductivity type doped layer 135 and between the source electrode 173 and the first conductivity type doped layer 137.

The drain electrode 175 may be located on the second surface, i.e., the lower surface, of the chip substrate 110. The upper surface of the drain electrode 175 may be in contact with the lower surface of the chip substrate 110. The drain electrode 175 may be in ohmic contact with the chip substrate 110. The region in contact with the drain electrode 175 within the chip substrate 110 may be doped at a relatively high concentration compared to other regions. However, embodiments are not limited thereto, and another layer may be additionally located between the drain electrode 175 and the chip substrate 110. For example, a silicide layer may be located between the drain electrode 175 and the chip substrate 110. The silicide layer may include a metal silicide material. The drain electrode 175 and the chip substrate 110 may be electrically smoothly connected by the metal silicide layer.

The drain electrode 175 may include a conductive material. For example, the drain electrode 175 may include a metal, a metal alloy, a conductive metal nitride, a metal silicide, a doped semiconductor material, a conductive metal oxide, or a conductive metal nitride. The drain electrode 175 may be made of the same material as the source electrode 173 or may be made of a different material.

For example, the drain electrode 175 may be include titanium (Ti), titanium nitride (TiN), titanium silicon nitride (TiSiN), titanium aluminum nitride (TiAlN), titanium carbide (TiC), titanium aluminum (TiAl), titanium aluminum carbonitride (TiAlC—N), titanium aluminum carbide (TiAlC), tantalum (Ta), tantalum carbide (TaC), tantalum nitride (TaN), tantalum carbonitride (TaCN), tantalum silicon nitride (TaSiN), tantalum titanium nitride (TaTiN), tantalum aluminum nitride (TaAlN), tungsten (W), tungsten nitride (WN), tungsten carbide (WC), aluminum (AI), copper (Cu), cobalt (Co), nickel (Ni), nickel vanadium (Ni—V), nickel platinum (Ni—Pt), vanadium (V), zinc (Zn), niobium (Nb), niobium nitride (NbN), niobium carbide (NbC), molybdenum (Mo), molybdenum nitride (MoN), molybdenum carbide (MoC), ruthenium (Ru), platinum (Pt), rhodium (Rh), palladium (Pd), iridium (Ir), osmium (Os), silver (Ag), gold (Au), or a combination thereof, but is not limited thereto. The source electrode 173 may be formed of a single layer or multiple layers. The drain electrode 175 may be formed of a single layer or multiple layers.

For example, the drain electrode 175 may include the same transition metal as the transition metal included in the bonding layer 300, for example, nickel (Ni) or nickel vanadium (Ni—V). In this example, as described above, when the transition metal of the drain electrode 175 is mixed with the bonding layer 300 during bonding, the contact characteristics of the drain electrode 175 may deteriorate. However, the first diffusion barrier layer 312 and the second diffusion barrier layer 322 of the bonding layer 300 may prevent the contact characteristics of the drain electrode 175 from deteriorating when the transition metal of the drain electrode 175 is mixed with the bonding layer 300 during bonding.

For example, the thickness of the drain electrode 175 may be greater than or equal to about 100 nm, for example, greater than or equal to about 1 μm, greater than or equal to about 2 μm, greater than or equal to about 3 μm, greater than or equal to about 4 μm, greater than or equal to about 5 μm, greater than or equal to about 6 μm, greater than or equal to about 7 μm, greater than or equal to about 8 μm, or greater than or equal to about 9 μm, and may be less than or equal to about 10 μm, for example less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm, and may be about 100 nm to about 10 μm, or about 100 nm to about 3 μm.

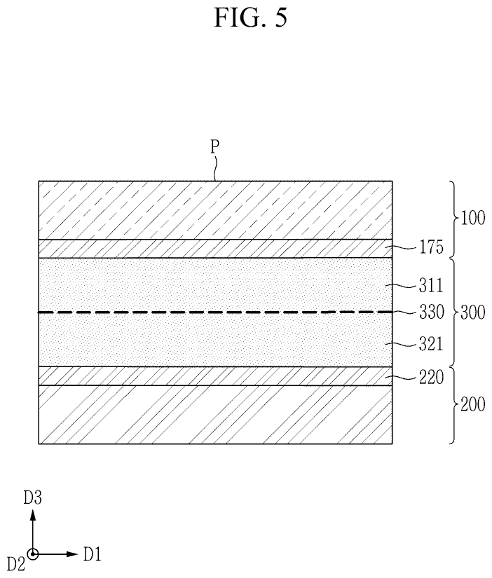

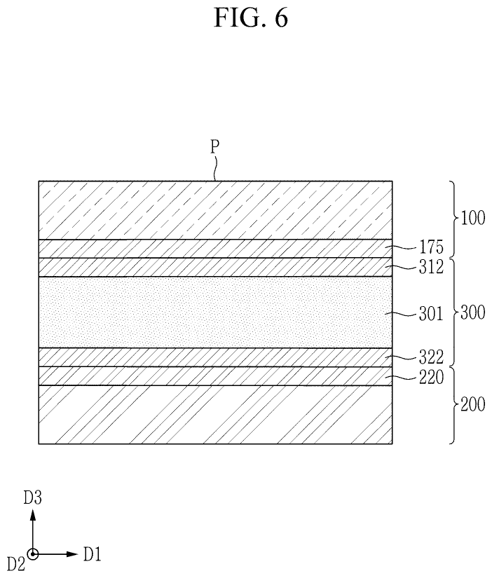

Hereinafter, a bonding layer 300 of a semiconductor device according to one or more embodiments will be described with reference to FIGS. 5 and 6.

FIGS. 5 and 6 are cross-sectional views illustrating semiconductor devices according to one or more embodiments, corresponding to the P region of FIG. 1.

The embodiments illustrated in FIGS. 5 and 6 are substantially identical to the embodiments illustrated in FIG. 2, and thus a description thereof will be omitted and the differences will be mainly explained. Additionally, the same reference numerals are used for the same components as in the previous embodiment.

Referring to FIG. 5, the bonding layer 300 may have a first layer 311 closer to the semiconductor chip 100 in the third direction D3, a second layer 321 closer to the substrate 200, and an interface layer 330 between the first layer 311 and the second layer 321. The bonding layer 300 may not have a first diffusion barrier layer 312 and a second diffusion barrier layer 322. For example, the second layer 321, the interface layer 330, and the first layer 311 may be sequentially stacked in the third direction D3. The first layer 311 may be in contact with the lower surface of the semiconductor chip 100, and for example, may be in contact with the lower surface of the drain electrode 175 of the semiconductor chip 100. The second layer 321 may be in contact with the upper surface of the substrate 200, and for example, may be in contact with the upper surface of the metal wiring layer 220 of the substrate 200.

Referring to FIG. 6, the bonding layer 300 may have a third layer 301, a first diffusion barrier layer 312 between the third layer 301 and the semiconductor chip 100, and a second diffusion barrier layer 322 between the third layer 301 and the substrate 200. For example, the second diffusion barrier layer 322, the third layer 301, and the first diffusion barrier layer 312 may be sequentially stacked in the third direction D3.

For example, the bonding layer 300 may not have an interface layer 330. Accordingly, the third layer 301 is a layer in which the first layer 311 and the second layer 321 may be combined, and since the first layer 311 and the second layer 321 do not have a distinct boundary, the first layer 311 and the second layer 321 may integrally form one layer. However, embodiments are not limited thereto, and the third layer 301 may have a relatively small amount of voids at the boundary between the first layer 311 and the second layer 321, in which case the boundary between the first layer 311 and the second layer 321 may be distinguishable. The third layer 301 includes a transition metal, a low-melting-point metal, and an alloy thereof, and may not include a noble metal.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor device comprising a substrate;
a semiconductor chip on the substrate; and
a bonding layer between the substrate and the semiconductor chip;
wherein the bonding layer comprises a transition metal, a low-melting-point metal having a melting point lower than a melting point of the transition metal, a noble metal, and an alloy thereof, and
wherein a percentage of the noble metal in the bonding layer is greater in a central portion of the bonding layer than at peripheral portions of the bonding layer in a first direction of the bonding layer.

2. The semiconductor device of claim 1, wherein the transition metal comprises nickel (Ni), nickel vanadium (Ni—V), vanadium (V), titanium (Ti), tantalum (Ta), tungsten (W), copper (Cu), cobalt (Co), zinc (Zn), niobium (Nb), molybdenum (Mo), or a combination thereof, the low-melting-point metal includes tin (Sn), lead (Pb), or a combination thereof, and
wherein the noble metal comprises silver (Ag), gold (Au), platinum (Pt), ruthenium (Ru), rhodium (Rh), palladium (Pd), iridium (Ir), osmium (Os), or a combination thereof.

3. The semiconductor device of claim 1, wherein the bonding layer comprises:
a first layer on the semiconductor chip;
a second layer on the substrate, and
an interface layer between the first layer and the second layer.

4. The semiconductor device of claim 3, wherein the first layer and the second layer comprise the transition metal, the low-melting-point metal, and the alloy thereof, and
wherein the interface layer comprises the transition metal, the low-melting-point metal, the noble metal, and the alloy thereof.

5. The semiconductor device of claim 3, wherein a percentage of the noble metal in the interface layer is greater than a percentage of the noble metal in the first layer and the second layer, and
wherein a percentage of the noble metal in a central portion of the interface layer is greater than a percentage of the noble metal on peripheral portions of the interface layer in the first direction of the interface layer.

6. The semiconductor device of claim 3, wherein a percentage of the noble metal in the interface layer gradually decreases from a central portion of the interface layer to peripheral portions of the interface layer in the first direction of the interface layer.

7. The semiconductor device of claim 3, wherein a percentage of the noble metal in the bonding layer is less than or equal to about 5 at %.

8. The semiconductor device of claim 3, wherein a thickness of the interface layer is less than or equal to about 50% of the thickness of the bonding layer.

9. The semiconductor device of claim 3, wherein a thickness of the bonding layer is 1 μm to 10 μm,
wherein a thickness of the interface layer is less than or equal to 20 nm, wherein a thickness of the first layer is 2 μm to 6 μm, and
wherein a thickness of the second layer is 2 μm to 6 μm.

10. The semiconductor device of claim 3, wherein the interface layer comprises in, and
wherein a percent by volume of voids included in the bonding layer is less than or equal to about 5 volume %.

11. The semiconductor device of claim 3, wherein the bonding layer comprises at least one of:
a first diffusion barrier layer between the semiconductor chip and the first layer; and
a second diffusion barrier layer between the substrate and the second layer.

12. The semiconductor device of claim 11, wherein the first diffusion barrier layer and the second diffusion barrier layer comprise:
titanium (Ti), titanium nitride (TIN), titanium tungsten (Ti—W), platinum (Pt), chromium (Cr), or a combination thereof.

13. The semiconductor device of claim 11, wherein a thickness of the first diffusion barrier layer in the first direction is 100 nm to about 10 μm, and wherein a thickness of the second diffusion barrier layer in the first direction is 100 nm to 10 μm.

14. The semiconductor device of claim 1, wherein the semiconductor chip comprises:
a drain electrode;
a first conductivity type semiconductor layer on the drain electrode;
second conductivity type doped well region included in the first conductivity type semiconductor layer;
a gate electrode on the first conductivity type semiconductor layer;
a gate insulation layer between the first conductivity type semiconductor layer and the gate electrode; and
a source electrode on the second conductivity type doped well region.

15. The semiconductor device of claim 14, wherein the semiconductor chip further comprises:
a first conductivity type doped layer on the first conductivity type semiconductor layer and included in the second conductivity type doped well region,

16. The semiconductor device of claim 14, wherein the drain electrode comprises titanium (Ti), titanium nitride (TiN), titanium silicon nitride (TiSiN), titanium aluminum nitride (TiAlN), titanium carbide (TiC), titanium aluminum (TiAl), titanium aluminum carbonitride (TiAlC—N), titanium aluminum carbide (TiAlC), tantalum (Ta), tantalum carbide (TaC), tantalum nitride (TaN), tantalum carbonitride (TaCN), tantalum silicon nitride (TaSiN), tantalum titanium nitride (TaTiN), tantalum aluminum nitride (TaAlN), tungsten (W), tungsten nitride (WN), tungsten carbide (WC), aluminum (AI), copper (Cu), cobalt (Co), nickel (Ni), nickel vanadium (Ni—V), nickel platinum (Ni—Pt), vanadium (V), zinc (Zn), niobium (Nb), niobium nitride (NbN), niobium carbide (NbC), molybdenum (Mo), molybdenum nitride (MON), molybdenum carbide (MoC), ruthenium (Ru), platinum (Pt), rhodium (Rh), palladium (Pd), iridium (Ir), osmium (Os), silver (Ag), gold (Au), or a combination thereof.

17. The semiconductor device of claim 16, wherein the drain electrode comprises the transition metal.

18. The semiconductor device of claim 16, wherein a thickness of the drain electrode is 100 nm to 10 μm.

19. A semiconductor device comprising
a substrate;
a semiconductor chip on the substrate; and
a bonding layer between the substrate and the semiconductor chip,
wherein the bonding layer comprises, in a first direction of the bonding layer, a first layer on the semiconductor chip, a second layer on the substrate, an interface layer between the first layer and the second layer, a first diffusion barrier layer between the semiconductor chip and the first layer, and a second diffusion barrier layer between the substrate and the second layer,
wherein the first layer and the second layer comprise nickel (Ni), tin (Sn), and an alloy thereof,
wherein the interface layer comprises nickel (Ni), tin (Sn), gold (Au), and an alloy thereof, and
wherein the first diffusion barrier layer and the second diffusion barrier layer comprise titanium (Ti), titanium nitride (TiN), titanium tungsten (Ti—W), platinum (Pt), chromium (Cr), or a combination thereof.

20. A semiconductor device comprising
a substrate;
a semiconductor chip on the substrate; and
a bonding layer between the substrate and the semiconductor chip;
wherein the semiconductor chip comprises:
a drain electrode,
a first conductivity type semiconductor layer on the drain electrode,
a second conductivity type doped well region in the first conductivity type semiconductor layer,
a gate electrode on the first conductivity type semiconductor layer,
a gate insulation layer between the first conductivity type semiconductor layer and the gate electrode, and
a source electrode on the second conductivity type doped well region,
wherein the bonding layer comprises a transition metal, a low-melting-point metal having a melting point lower than that of the transition metal, and an alloy thereof, and
wherein the drain electrode of the semiconductor chip comprises the transition metal.
